(19) United States
(12) Patent Application Publication
(10) Pub. No.: US 2017/0256449 A1
(43) Pub. Date: Sep. 7, 2017

(54) METHODS OF FORMING CONDUCTIVE STRUCTURES WITH DIFFERENT MATERIAL COMPOSITIONS IN A METALLIZATION LAYER

(71) Applicant: GLOBALFOUNDRIES Inc., Grand Cayman (KY)

(72) Inventors: Xunyuan Zhang, Albany, NY (US); Ruilong Xie, Niskayuna, NY (US); Vimal Kamineni, Mechanicville, NY (US)

(21) Appl. No.: 15/062,328

(22) Filed: Mar. 7, 2016

(51) Int. Cl. H01L 21/768

(52) U.S. Cl. CPC H01L 21/76877; H01L 21/76802; H01L 21/76846; H01L 21/76883

(57) ABSTRACT

One illustrative method disclosed herein includes, among other things, forming a first trench and a second trench in a layer of insulating material, the first trench having a first lateral critical dimension, the second trench having a second lateral critical dimension that is greater than the first lateral critical dimension of the first trench, forming a first conductive structure in the first trench, wherein a first bulk metal material constitutes a bulk portion of the first conductive structure, and forming a second conductive structure in the second trench, wherein a second bulk metal material constitutes a bulk portion of the second conductive structure and wherein the first bulk metal material and second bulk metal material are different materials.

### BACKGROUND OF THE INVENTION

### 1. Field of the Invention

Generally, the present disclosure relates to the manufacture of semiconductor devices, and, more specifically, to various methods of forming conductive structures with different material compositions in a metallization layer.

### 2. Description of the Related Art

In modern integrated circuits, such as microprocessors, storage devices and the like, a very large number of circuit elements, especially transistors, are provided and operated on a restricted chip area. Immense progress has been made over recent decades with respect to increased performance and reducing the physical size (feature sizes) of circuit elements, such as transistors. Field effect transistors (FETs) come in a variety of configurations, e.g., planar transistor devices, FinFET devices, nanowire devices, etc. Irrespective of the form of the FET, they have a gate electrode, a source region, a drain region and a channel region positioned between the source and drain regions. The state of the field effect transistor (“ON” or “OFF”) is controlled by the gate electrode. Upon the application of an appropriate control voltage to the gate electrode, the channel region becomes conductive, thereby allowing current to flow between the source and drain regions.

To improve the operating speed of FETs, and to increase the density of FETs on an integrated circuit device, device designers have greatly reduced the physical size of FETs over the years, particularly the channel length of transistor devices. As a result of the reduced dimensions of the transistor devices, the operating speed of the circuit components has been increased with every new device generation, and the “packing density,” i.e., the number of transistor devices per unit area, in such products has also increased during that time. Such improvements in the performance of transistor devices has reached the point where one limiting factor relating to the operating speed of the final integrated circuit product is no longer the individual transistor element but the electrical performance of the complex wiring system that is formed above the device level where the actual semiconductor-based circuit elements, such as transistors, are formed in and above the semiconductor substrate.

Typically, due to the large number of circuit elements and the required complex layout of modern integrated circuits, the electrical connections or “wiring arrangement” for the individual circuit elements cannot be established within the same device level where the circuit elements are manufactured. Accordingly, the various electrical connections that constitute the overall wiring pattern for the integrated circuit product are formed in one or more additional so-called “metallization layers” that are formed or stacked above the device level of the product. A typical integrated circuit product may contain several of such metallization layers, e.g., 7-12, depending upon the complexity of the integrated circuit product.

Each of these metallization layers is typically comprised of a layer of insulating material with conductive metal lines and/or conductive vias formed in the layer of material. Generally, the conductive lines provide the intra-level (i.e., within layer) electrical connections, while the conductive vias provide the inter-level connections or vertical connections between different metallization layers or levels. These conductive lines and conductive vias may be comprised of a variety of different materials, e.g., copper, with appropriate barrier layers, etc. The first metallization layer in an integrated circuit product is typically referred to as the “M1” layer, while the conductive vias that are used to establish electrical connection between the M1 layer and lower level conductive structures that physically contact the devices are typically referred to as “V0” vias. For current advanced integrated circuit products, the conductive lines and conductive vias in these metallization layers are typically comprised of copper, and they are formed in layers of insulating material using known damascene or dual-damascene techniques. As noted above, additional metallization layers are formed above the M1 layer, e.g., M2/V1, M3/V2, etc. Within the industry, conductive structures below the V0 level are generally considered to be “device-level” contacts or simply “contacts,” as they contact the “device” (e.g., a transistor) that is formed in the silicon substrate.

However, with each advancing generation of products, the critical dimension of the conductive structures, e.g., the lateral width of a conductive line, tends to decrease as well. In some applications a single metallization layer may have conductive structures with significantly different lateral widths. Filling relatively small trenches in a layer of insulating material with copper material, using electroplating or electroless plating techniques, can be difficult. Moreover, even though the overall critical dimension of these conductive structures decreases, the thickness of the barrier layer(s) that must be formed in these trenches remains about the same, i.e., the barrier layer thickness does not scale down (at least not significantly) as the overall critical dimension (lateral width) of the conductive structure, e.g., a conductive line, is reduced. Accordingly, there is less space within the trench for the more conductive copper material, i.e., the bulk metal of the conductive structure, and, in a relative sense, the current density within such smaller conductive structures increases during operation. In turn, this increase in current density of the bulk copper material can lead to more undesirable electromigration of the copper material during operation of the IC product, which can reduce product performance and/or lead to product failure.

Investigations have been made with regard to using alternative materials, e.g., cobalt, etc., to replace copper as the bulk portion of the conductive structures. FIGS. 1A-1D depict one illustrative prior art method of forming conductive structures in a metallization layer on an integrated circuit product using such alternative materials. FIG. 1A is a simplified view of an illustrative metallization layer of a prior art integrated circuit product 10. At this point in the fabrication process, the product 10 comprises an etch stop layer 12 and a layer of insulating material 14, e.g., a low-k material, silicon dioxide, etc. A plurality of relatively narrow trenches 16 (with a critical dimension 16A) and a relatively wider trench 18 (with a critical dimension 18A) have been defined in the layer of insulating material 14 by performing any of a variety of different known prior art processing techniques. In one illustrative embodiment, the critical dimension 16A may be about 10-20 nm, while the critical dimension 18A may be about 30-150 nm. As depicted, a barrier layer 20 was initially formed across the layer 14 and in the trenches 16, 18. In practice the simplistically depicted barrier layer 20 may comprise multiple layers of material. Thereafter, a conformal deposition process was performed to deposit a bulk metal layer 22, e.g., cobalt, in the trenches 16, 18. The bulk metal layer 22 may have a thickness, e.g., about 10-20 nm, such that it substantially fills the smaller trenches 16 but only “lines” the wider trench 18.

FIG. 1B depicts the product 10 after an anneal process, at a temperature of about 300-400° C., was performed on the product. The anneal process causes the material of the metal layer 22 to reflow and recrystallize. As depicted, by performing the anneal process, a substantial portion of the sidewalls of the larger trench 18 are effectively cleared of the bulk metal layer 22 (leaving the barrier layer 20 in position), while a portion 22X of the bulk metal layer 22 remains positioned at the bottom of the wider trench 18.

FIG. 1C depicts the product 10 after an overburden of additional bulk metal material 22A, e.g., cobalt, was formed on the product 10. The additional bulk metal material 22A may be formed by performing a physical vapor deposition (PVD) process or by performing an electroplating process. The outline of the original bulk metal layer 22 is shown in FIG. 1C just for reference purposes as the bulk metal materials 22, 22A will effectively merge with one another during the formation process.

FIG. 1D depicts the product 10 after one or more chemical mechanical polishing (CMP) operations were performed to remove the excess amounts of the various materials positioned above the upper surface 14A of the layer of insulating material 14. These operations result in the formation of a wide conductive structure 30 in the wider trench 18 and a narrow conductive structure 32 in each of the relatively narrow trenches 16.

In general, copper has a lower electrical resistivity (higher electrical conductivity) than other metals, such as cobalt. However, it is generally known that, for conductive structures where copper is the bulk portion of the structure, the formation of very small copper-containing conductive structures (e.g., structures having a lateral width (critical dimension) of about 20 nm or less), the electrical resistivity of copper increases. Other materials, such as cobalt, that may be used as the bulk portion of a conductive structure also experience an increase in electrical resistivity of the bulk metal material in such small conductive structures. However, for such small structures, the increase in the electrical resistivity of a cobalt conductive structure is less than the corresponding increase in the electrical resistivity of a corresponding copper conductive structure. Thus, while use of the alternative metal material 22 in the narrow conductive structures 32 may provide benefits relative to the use of copper in such smaller conductive structures 32, the same is not the case for the use of such alternative bulk metal materials for the larger or wider conductive structure 30 for several reasons. First, given the relatively larger volume of the bulk portion, e.g., the bulk metals 22/22A, of the wide conductive structure 30, copper does not experience a significant increase in electrical resistance when formed in such relatively wide trenches 18. Second, given the normal difference in the basic electrical properties, e.g., electrical resistance, of copper (relatively lower) and the alternative material 22/22A (relatively higher), the benefits obtained when using the alternative metal material 22 when forming the smaller conductive structures 32 are not present as it relates to the formation of the larger conductive structures 30 using such alternative metal materials 22/22A. Third, in some cases, the use of such alternative bulk metal materials 22/22A in the wider conductive structure 30 may result in the wider conductive structure 30 having an overall higher electrical resistance than would be the case if the wider conductive structure 30 was formed using copper as the bulk portion of the wider conductive structure 30.

The present disclosure is directed to various methods of forming conductive structures with different material compositions in a metallization layer that may solve or at least reduce some of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming conductive structures with different material compositions in a metallization layer. One illustrative method disclosed herein includes, among other things, forming a first trench and a second trench in a layer of insulating material, the first trench having a first lateral critical dimension, the second trench having a second lateral critical dimension that is greater than the first lateral critical dimension of the first trench, forming a first conductive structure in the first trench, wherein a first bulk metal material constitutes a bulk portion of the first conductive structure, and forming a second conductive structure in the second trench, wherein a second bulk metal material constitutes a bulk portion of the second conductive structure, and wherein the first bulk metal material and the second bulk metal material are different materials.

Another illustrative method disclosed herein includes, among other things, forming a first trench and a second trench in at least one layer of insulating material, the first trench having a first lateral critical dimension, the second trench having a second lateral critical dimension that is greater than the first lateral critical dimension of the first trench, depositing a first bulk metal layer in both the first and second trenches and performing at least one first process operation to remove portions of the first bulk metal layer while leaving a remaining portion of the first bulk metal layer positioned within the first trench. In this embodiment, the method also includes depositing a second bulk metal layer above the remaining portion of the first bulk metal layer and within the second trench so as to overfill the second trench with the second bulk metal layer, wherein the first bulk metal layer and the second bulk metal layer comprise different materials, and performing at least one second process operation to remove materials positioned above an upper surface of the at least one layer of insulating material so as to define a narrow conductive structure positioned in the first trench and a wide conductive structure in the second trench.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1D depict one illustrative prior art method of forming conductive structures in a metallization layer on an integrated circuit product;

FIGS. 2A-2D depict one illustrative method disclosed herein for forming conductive structures with different material compositions in a metallization layer;

FIGS. 3A-3E depict another illustrative method disclosed herein for forming conductive structures with different material compositions in a metallization layer;

FIGS. 4A-4E depict yet another illustrative method disclosed herein for forming conductive structures with different material compositions in a metallization layer;

FIGS. 5A-5E depict another illustrative method disclosed herein for forming conductive structures with different material compositions in a metallization layer;

FIGS. 6A-6E depict a further illustrative method disclosed herein for forming conductive structures with different material compositions in a metallization layer; and

FIGS. 7A-7E depict another illustrative method disclosed herein for forming conductive structures with different material compositions in a metallization layer.

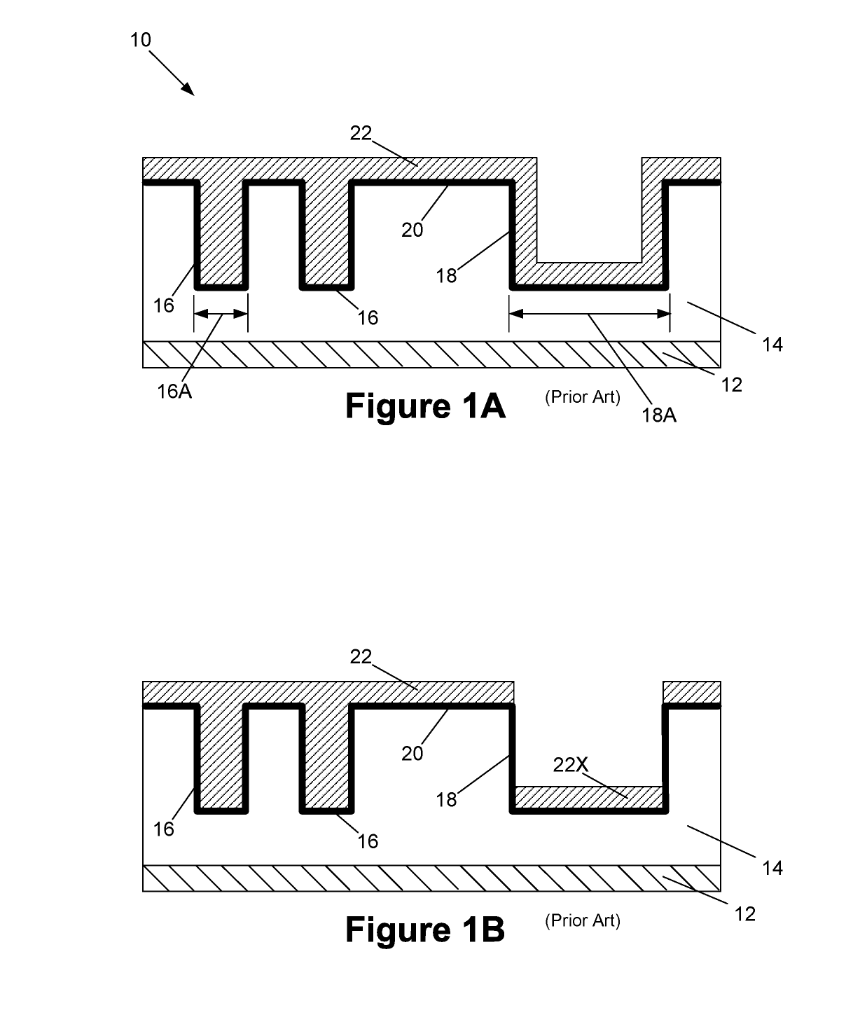

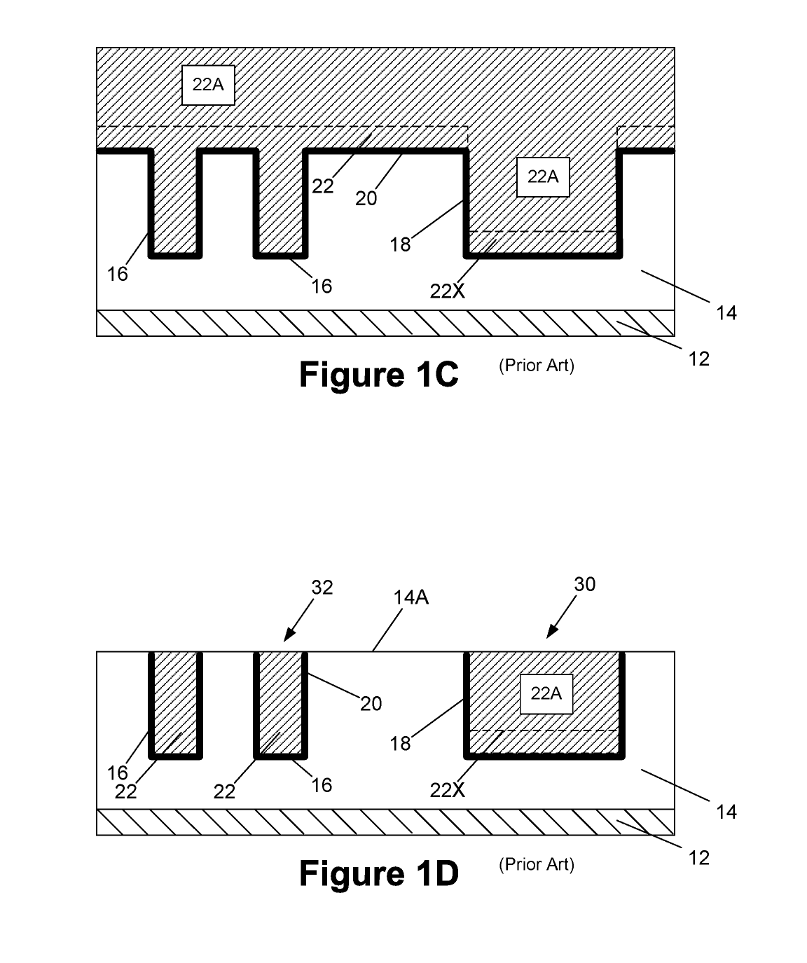

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure is directed to various methods of forming conductive structures with different material compositions in a metallization layer. As will be readily apparent to those skilled in the art upon a complete reading of the present application, the methods disclosed herein may be employed when forming metallization layers that are electrically coupled to a variety of different semiconductor devices, e.g., transistors, memory cells, resistors, etc., and may be employed when forming metallization layers for a variety of different integrated circuit products, including, but not limited to, ASIC's, logic products, memory products, system-on-chip products, etc. With reference to the attached drawings, various illustrative embodiments of the methods disclosed herein will now be described in more detail. The various layers of material described below may be formed by any of a variety of different known techniques, e.g., a chemical vapor deposition (CVD) process, an atomic layer deposition (ALD) process, a thermal growth process, spin-coating techniques, etc. Moreover, as used herein and in the attached claims, the word “adjacent” is to be given a broad interpretation and should be interpreted to cover situations where one feature actually contacts another feature or is in close proximity to that other feature.

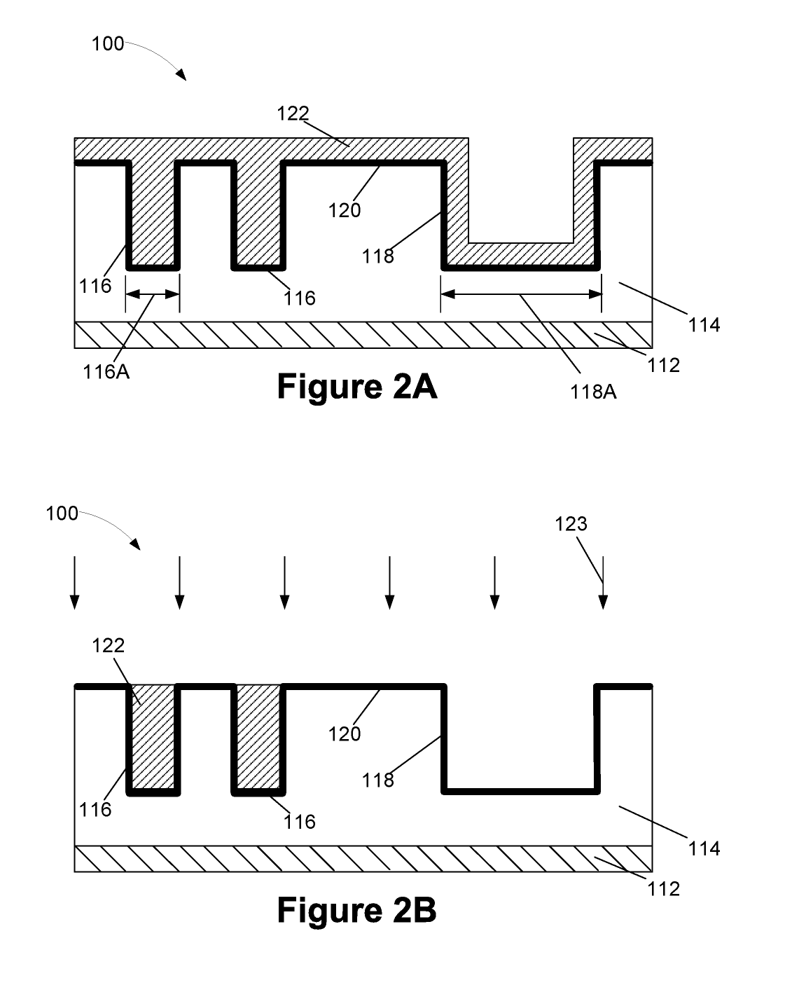

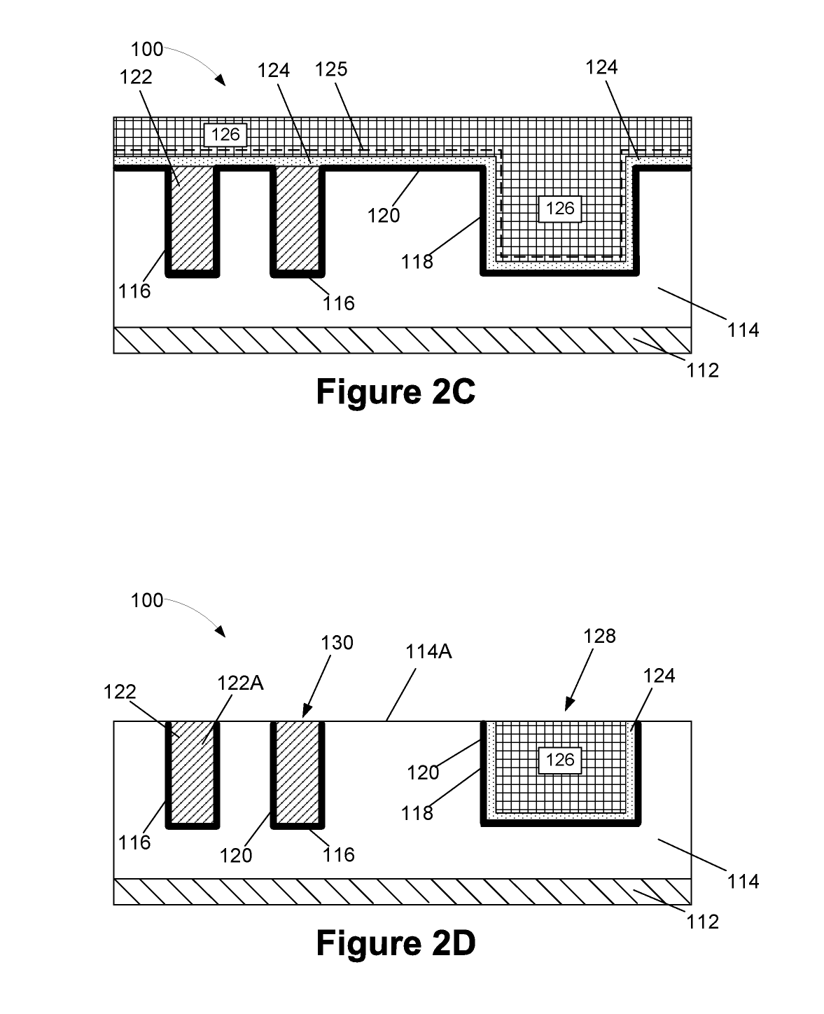

FIGS. 2A-2D depict one illustrative method disclosed herein for forming conductive structures with different material compositions in a metallization layer formed on an integrated circuit product 100. The product 100 may be any type of integrated circuit product that employs any type of a conductive structure, such as a conductive line or via, commonly found on integrated circuit products, including, but not limited to, logic products, memory products, system on chip products, etc.

FIG. 2A is a simplified view of an illustrative metallization layer of an integrated circuit product 100. The metallization layer depicted herein is intended to be representative of any metallization layer formed at any level on the product 100 (e.g., the M1 layer and/or any metallization layer formed above the M1 layer), and it is typically formed during so-called BEOL (Back-End-Of-Line) processing operations. At the point of fabrication depicted in FIG. 2A, the product 100 comprises an etch stop layer 112 and a layer of insulating material 114. The etch stop layer 112 may be comprised of a material such as silicon nitride. The layer of insulating material 114 may be comprised of a variety of different materials, e.g., a low-k material (k value of 3.3 or less), silicon dioxide, etc. A plurality of relatively narrow trenches 116 (with a critical dimension 116A) and a relatively wider trench 118 (with a critical dimension 118A) have been defined in the layer of insulating material 114 by performing any of a variety of different prior art techniques, e.g., performing one or more etching processes through a patterned etch mask. In one illustrative embodiment, in current day products 100, the critical dimension 116A may be about 10-20 nm, while the critical dimension 118A may be about 30-150 nm. In one illustrative embodiment, the critical dimension 118A of the wider trench 118 may be at least three times greater than the critical dimension 116A of the narrower trench 116.

With continuing reference to FIG. 2A, a simplistically depicted first barrier layer 120 was initially formed across the layer 114 and in the trenches 116, 118. In practice, the depicted barrier layer 120 may comprise multiple layers of material and it may have a thickness of about 1-3 nm. The first barrier layer 120 may be comprised of a variety of different materials, e.g., one or more layers of titanium nitride, tantalum nitride, tantalum, titanium, etc. The material(s) selected for the first barrier layer 120 may be based upon the material selected for a first bulk metal layer 122 (discussed below) that will be formed after the first barrier layer 120 is formed. Additionally, as used herein and in the claims, the term “barrier layer” should be understood to also include any so-called adhesion layers, if present, in the final conductive structures. The first barrier layer 120 may be formed by performing any of a variety of techniques, e.g., a conformal ALD process, PVD process, etc. Thereafter, a conformal deposition process was performed to deposit a first bulk metal layer 122, e.g., cobalt, etc., in the trenches 116, 118. The first bulk metal layer 122 may have a thickness, e.g., about 10-20 nm, such that it substantially overfills the smaller trenches 116 but only “lines” the wider trench 118. That is, the first bulk metal layer 122 is formed to such a thickness that it essentially “pinches off” in the smaller trenches 116. Of course, some relatively small voids (not shown) may be present within the bulk metal layer material 122 within the smaller trenches 116 due to the pinching-off of the first bulk metal layer 122.

FIG. 2B depicts the product after a timed, isotropic etching process 123 was performed on the product 100. At the completion of the etching process 123, substantially all of the material of the first bulk metal layer 122 has been removed from the product 100 except within the smaller trenches 116 where the material of the first bulk metal layer 122 substantially fills the smaller trenches 116. Note that substantially all of the material of the first bulk metal layer 122 has been cleared from the wider trench 118.

FIG. 2C depicts the product after several process operations were performed. First, a simplistically depicted second barrier layer 124 was initially formed above the first barrier layer 120, above the material of the first bulk metal layer 122 in the smaller trenches 116 and on the first barrier layer 120 within the larger trench 118. Thereafter, in one embodiment, a seed layer 125 (depicted by a dashed line) was formed on the second barrier layer 124. Then, a second bulk metal layer 126, e.g., copper, was formed on the product 100 so as to overfill the wider trench 118. The second bulk metal layer 126 is made of a different material than that of the first bulk metal layer 122. However, in some applications, the seed layer 125 may not be needed. For example, in some applications, after the formation of the second barrier layer 124, the second bulk metal layer 126 may be formed by performing an electoless plating process or by performing a deposition process, e.g., a CVD or a PVD process. In one illustrative embodiment, the second bulk metal layer 126 may be a bulk copper layer and the seed layer 125 may be a copper seed layer. In another particular embodiment, the second bulk metal layer 126 may be a bulk copper layer while the first bulk metal layer 122 may be made of, for example, cobalt. In practice, the depicted second barrier layer 124 may comprise one or more layers of material and it may have a thickness of about 1-3 nm. The second barrier layer 124 may be comprised of a variety of different materials, e.g., one or more layers of titanium nitride, tantalum nitride, tantalum, titanium, etc. The material(s) selected for the second barrier layer 124 may be based upon the material selected for a second bulk metal layer 126. The second barrier layer 124 may be formed by performing a variety of techniques, e.g., a conformal ALD process, PVD process, etc. In some applications, the material(s) of the first barrier layer 120 and the material(s) of the second barrier layer 124 may be different, although that situation is not required in all applications.

FIG. 2D depicts the product 100 after one or more chemical mechanical polishing (CMP) operations were performed to remove the excess amounts of the various materials positioned above the upper surface 114A of the layer of insulating material 114. These operations result in the formation of a wide conductive structure 128 in the wider trench 118 and a narrow conductive structure 130 in each of the relatively narrow trenches 116. As depicted, in this example, the wide conductive structure 128 is comprised of the first barrier layer 120, the second barrier layer 124 and the second bulk metal layer 126, wherein the second bulk metal layer 126 constitutes the bulk of the conductive portion of the wide conductive structure 128, i.e., the primary metal material of the conductive structure 128 other than the barrier layers 120, 124. In contrast, the narrow conductive structure 130 is comprised of the first barrier layer 120 and the first bulk metal layer 122, wherein the first bulk metal layer 122 constitutes the bulk of the conductive portion of the narrow conductive structure 130, i.e., the primary metal material of the narrow conductive structure 130 other than the barrier layer 120.

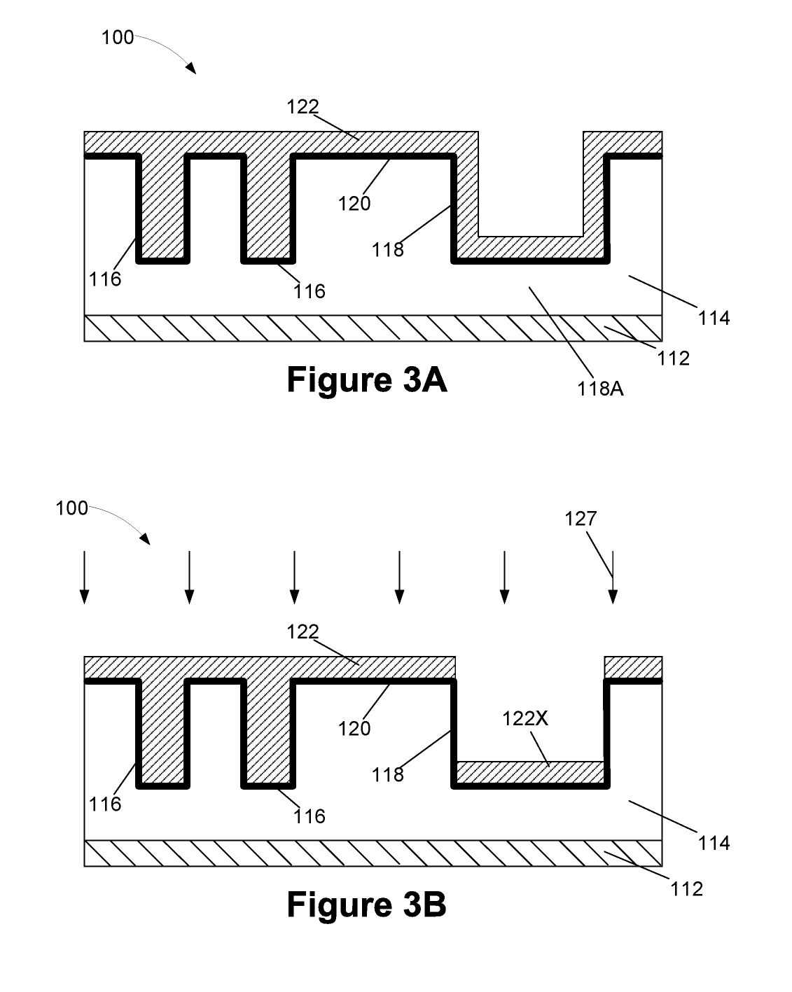

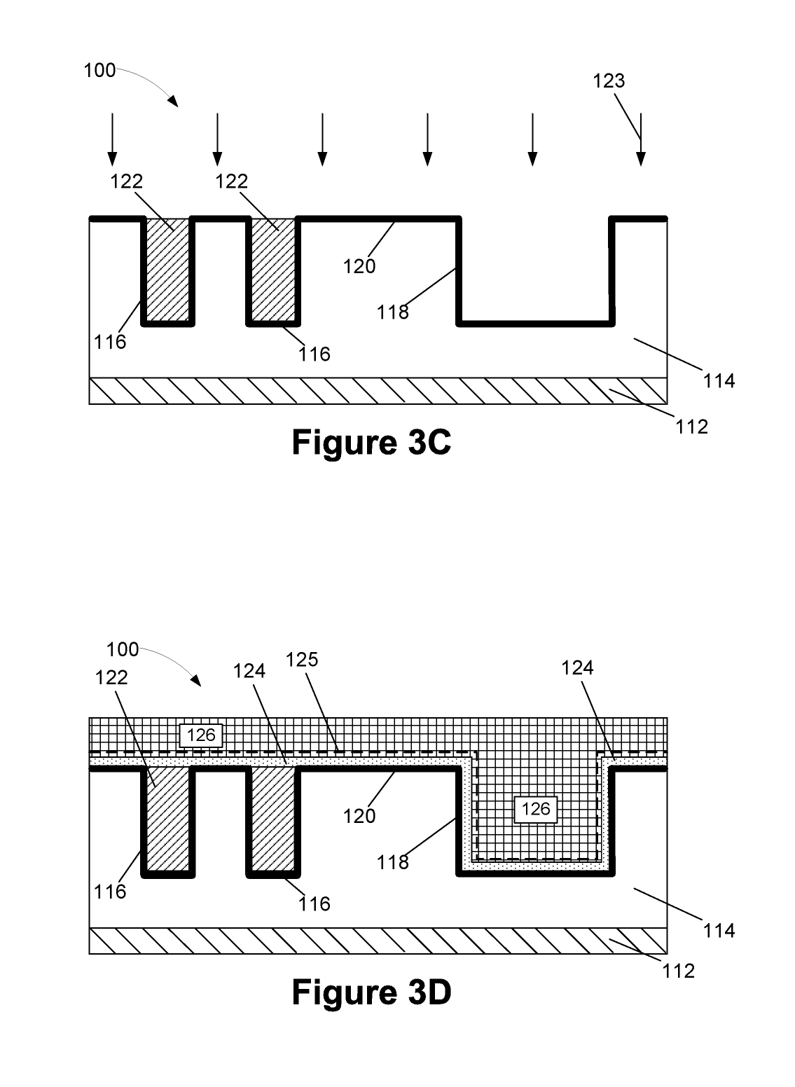

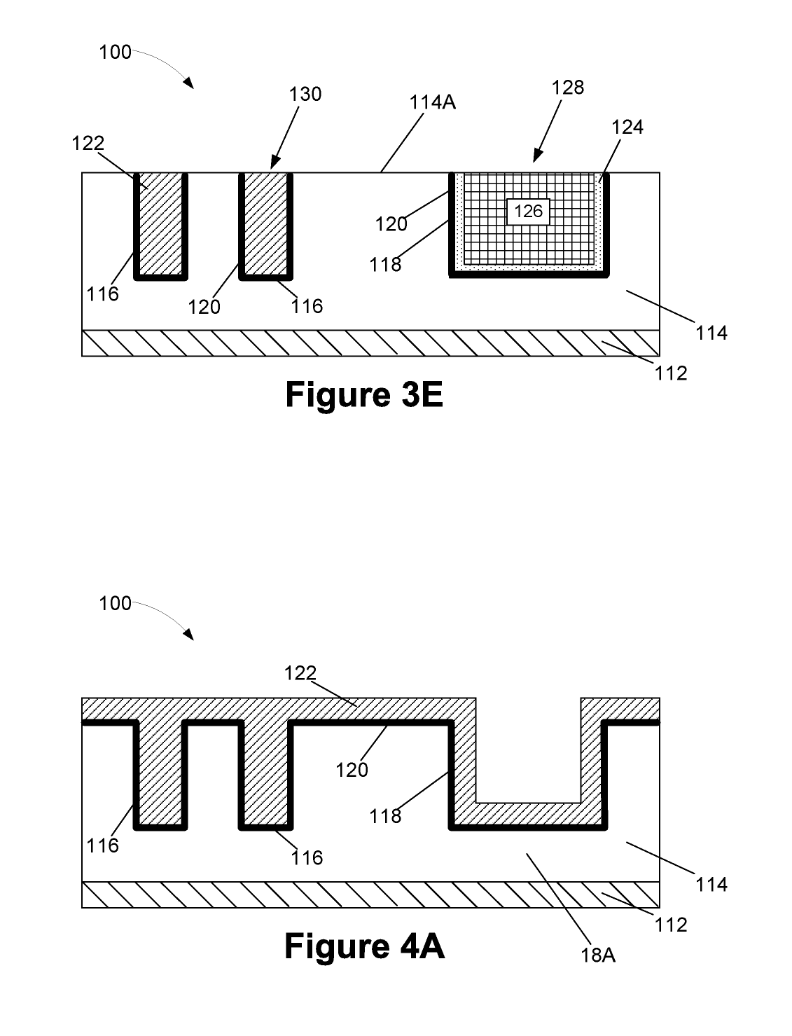

FIGS. 3A-3E depict another illustrative method disclosed herein for forming conductive structures with different material compositions in a metallization layer on the integrated circuit product 100. FIG. 3A depicts the product 100 at a point in fabrication that corresponds to that depicted in FIG. 2A.

FIG. 3B depicts the product 100 after an anneal process 127, at a temperature of about 300-400° C., was performed on the product 100. The anneal process 127 causes the material of the first bulk metal layer 122 to reflow and recrystallize. As depicted, by performing this anneal process 127, a substantial portion of the sidewalls of the larger trench 118 are effectively cleared of the first bulk metal layer 122 (leaving the barrier layer 120 in position), while a portion 122X of the first bulk metal layer 122 remains positioned at the bottom of the wider trench 118. In one illustrative embodiment, the portion 122X may have a thickness on the order of about 10-30 nm.

FIG. 3C depicts the product after the above-described timed, isotropic etching process 123 was performed on the product 100. At the completion of etching process 123, substantially all of the material of the first bulk metal layer 122 has been removed from the product 100 except within the smaller trenches 116 where the material of the first bulk metal layer 122 substantially fills the smaller trenches 116. Note that material of the first bulk metal layer 122 has been cleared from the wider trench 118.

FIG. 3D depicts the product 100 after the above-described second barrier layer 124, seed layer 125 and second bulk metal layer 126 were formed on the product 100.

FIG. 3E depicts the product 100 after one or more chemical mechanical polishing (CMP) operations were performed to remove the excess amounts of the various materials positioned above the upper surface 114A of the layer of insulating material 114. These operations result in the formation of the wide conductive structure 128 in the wider trench 118 and the narrow conductive structure 130 in each of the relatively narrow trenches 116. As depicted, the wide conductive structure 128 is comprised of the first barrier layer 120, the second barrier layer 124 and the second bulk metal layer 126, wherein the second bulk metal layer 126 constitutes the bulk of the wide conductive structure 128, i.e., the primary metal material of the wide conductive structure 128 other than the barrier layers 120, 124. In contrast, the narrow conductive structure 130 is comprised of the first barrier layer 120 and the first bulk metal layer 122, wherein the first bulk metal layer 122 constitutes the bulk of the conductive portion of the narrow conductive structure 130, i.e., the primary metal material of the conductive structure 130 other than the barrier layer 120.

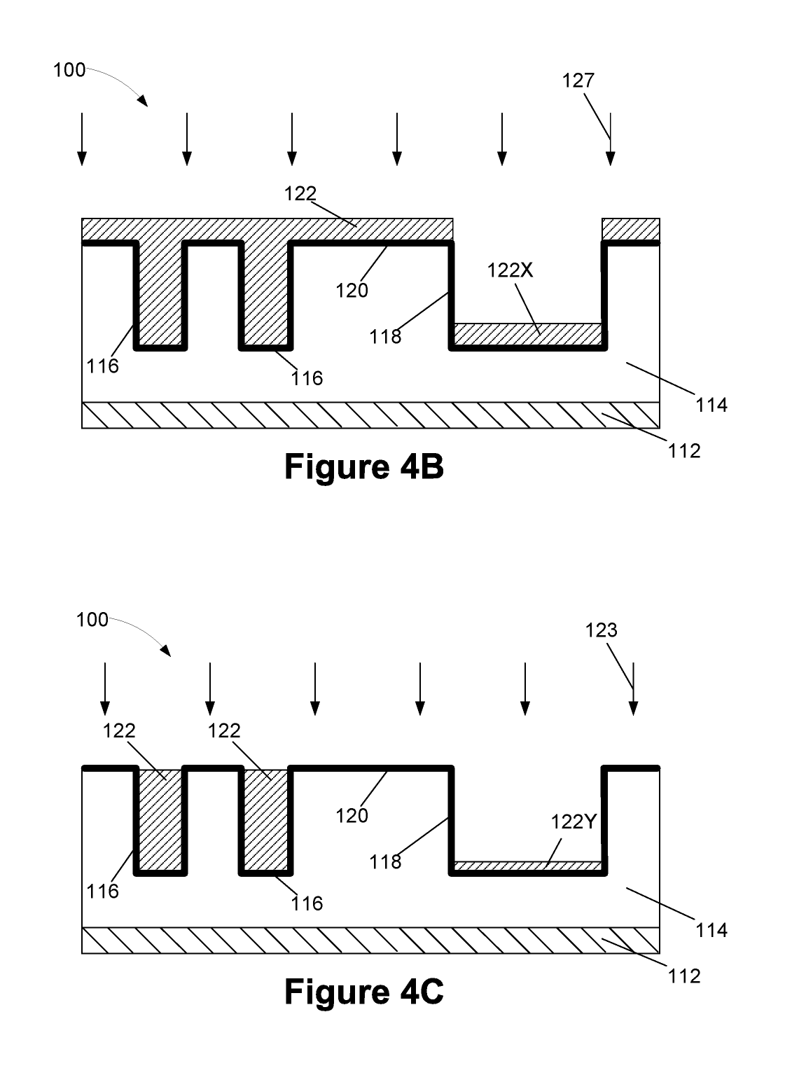

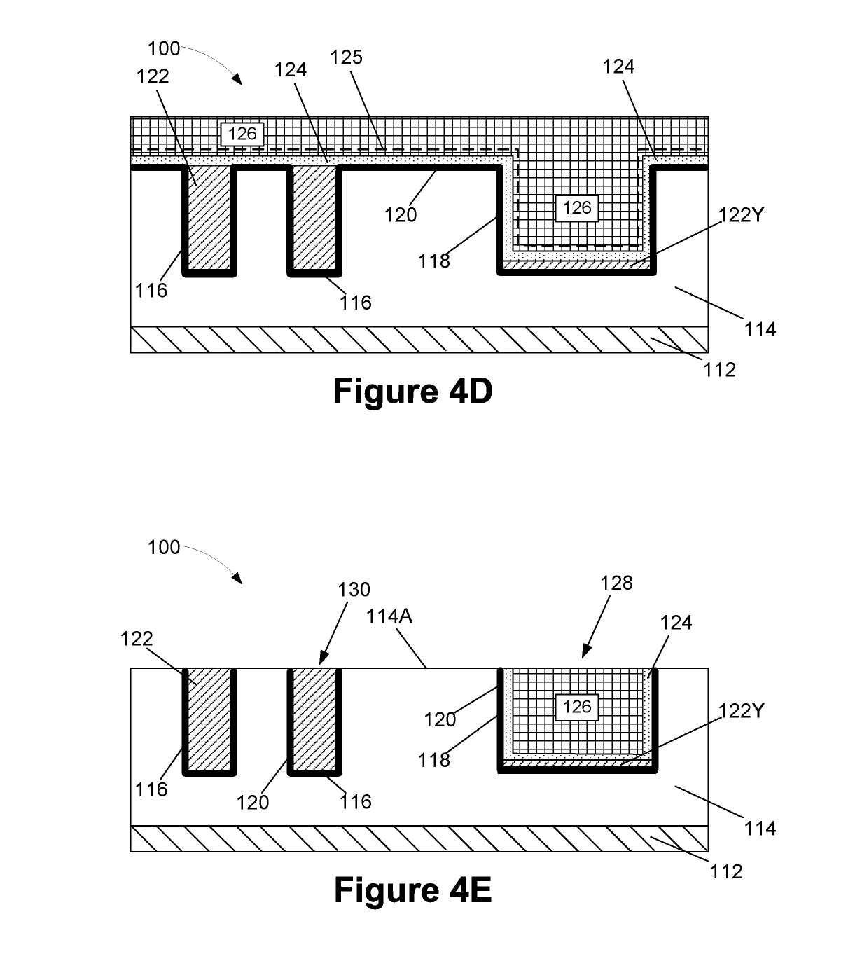

FIGS. 4A-4E depict yet another illustrative method disclosed herein for forming conductive structures with different material compositions in a metallization layer on the integrated circuit product 100. FIG. 4A depicts the product 100 at a point in fabrication that corresponds to that depicted in FIG. 2A.

FIG. 4B depicts the product 100 after the above-described anneal process 127 was performed on the product 100. As depicted, by performing this anneal process 127, a substantial portion of the sidewalls of the larger trench 118 are effectively cleared of the first bulk metal layer 122, while a portion 122X of the first bulk metal layer 122 remains positioned at the bottom of the wider trench 118.

FIG. 4C depicts the product after the above-described timed, isotropic etching process 123 was performed on the product 100. However, in this embodiment, the etching process 123 is performed for a duration such that, at the completion of etching process 123, a relatively thin portion 122Y of the material of the first bulk metal layer 122 remains positioned at the bottom of the larger trench 118. As before, at the completion of the etching process 123, the material of the first bulk metal layer 122 substantially fills the smaller trenches 116. In one illustrative embodiment, the portion 122Y may have a thickness on the order of about 3-10 nm.

FIG. 4D depicts the product 100 after the above-described second barrier layer 124, the seed layer 125 and the second bulk metal layer 126 were formed on the product 100.

FIG. 4E depicts the product 100 after one or more chemical mechanical polishing (CMP) operations were performed to remove the excess amounts of the various materials positioned above the upper surface 114A of the layer of insulating material 114. These operations result in the formation of the wide conductive structure 128 in the wider trench 118 and the narrow conductive structure 130 in each of the relatively narrow trenches 116. As depicted, in this embodiment, the wide conductive structure 128 is comprised of the first barrier layer 120, the second barrier layer 124, the portion 122Y of the first bulk metal layer 122 and the second bulk metal layer 126. Even in this embodiment where the portion 122Y of the first bulk metal layer 122 is part of the wide conductive structure 128, the second bulk metal layer 126 portion of the wide conductive structure 128 still constitutes the bulk conductive portion of the overall wide conductive structure 128, i.e., the material of the second bulk material layer 126 is the primary metal material of the conductive structure 128 other than the barrier layers 120, 124 and the portion 122Y of the first bulk metal layer 122. For example, depending upon the thickness of the portion 122Y of the first bulk metal layer 122, the portion of the second bulk metal layer 126 of the conductive structure 128 may amount to about 60-90 percent of the overall volume of conductive materials that, collectively, define the wide conductive structure 128. As before, in this embodiment, the narrow conductive structure 130 is comprised of the first barrier layer 120 and the first bulk metal layer 122, wherein the first bulk metal layer 122 constitutes a bulk of the conductive portion of the narrow conductive structure 130, i.e., the primary metal material of the narrow conductive structure 130 other than the barrier layer 120.

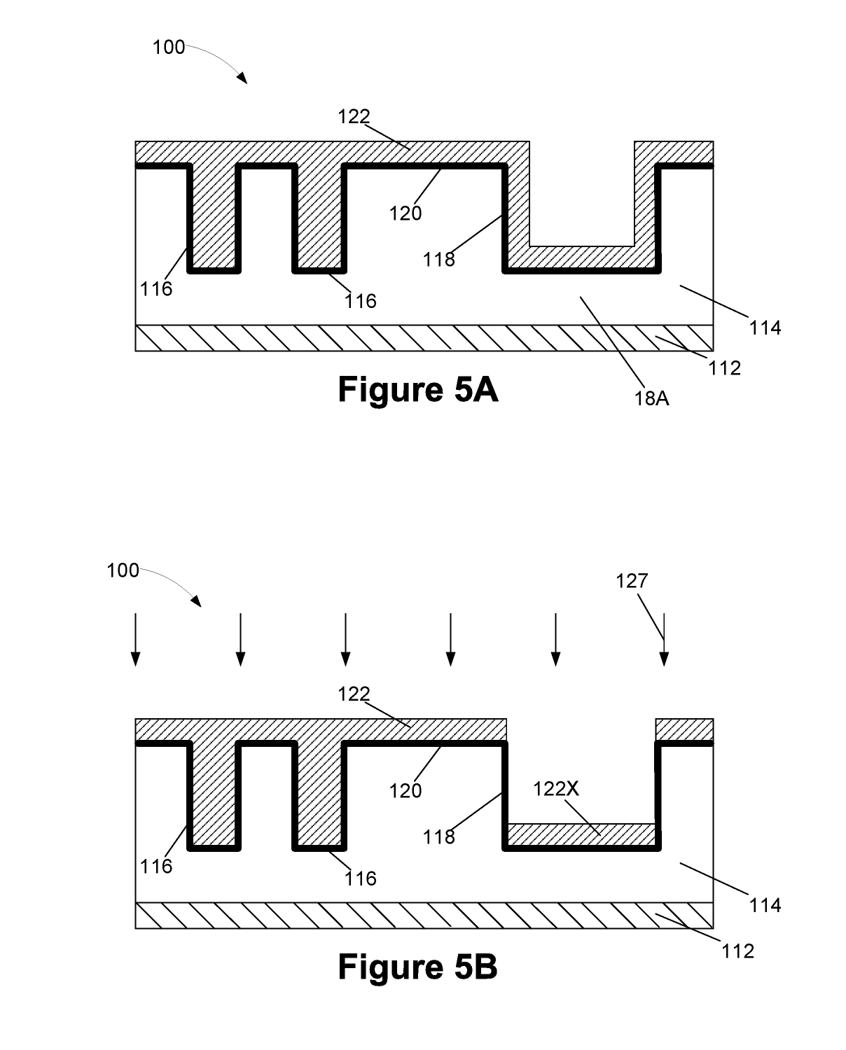

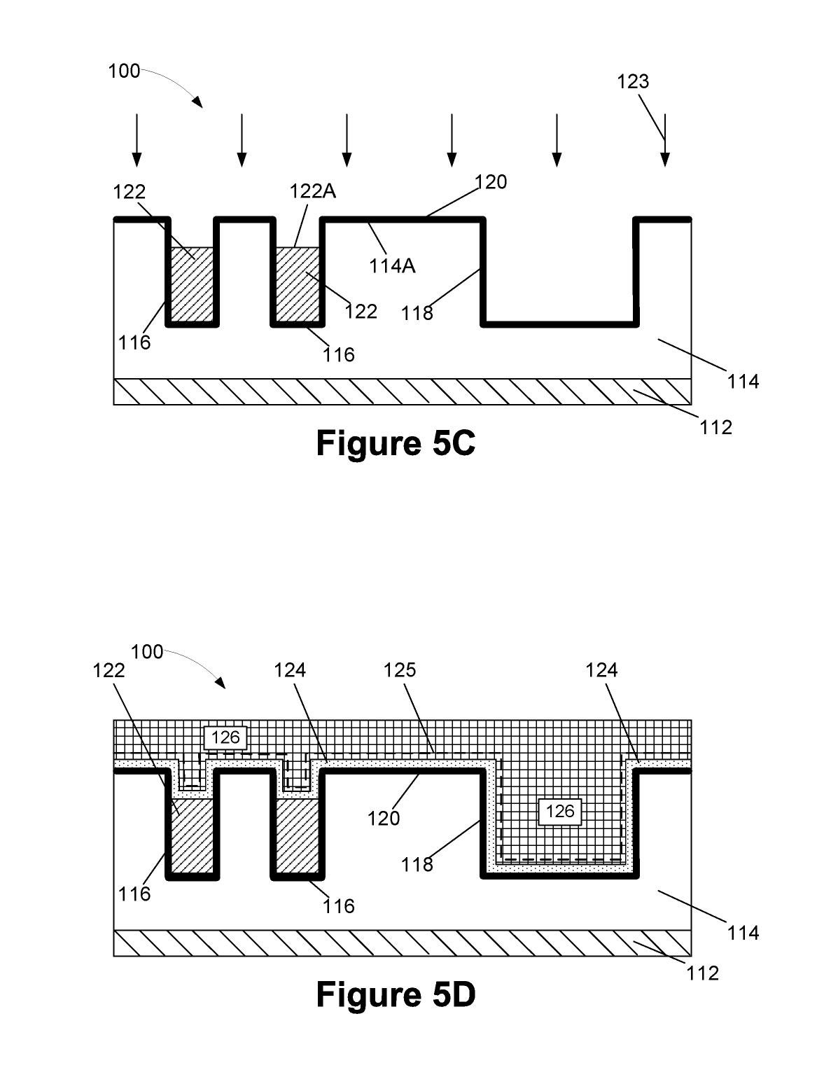

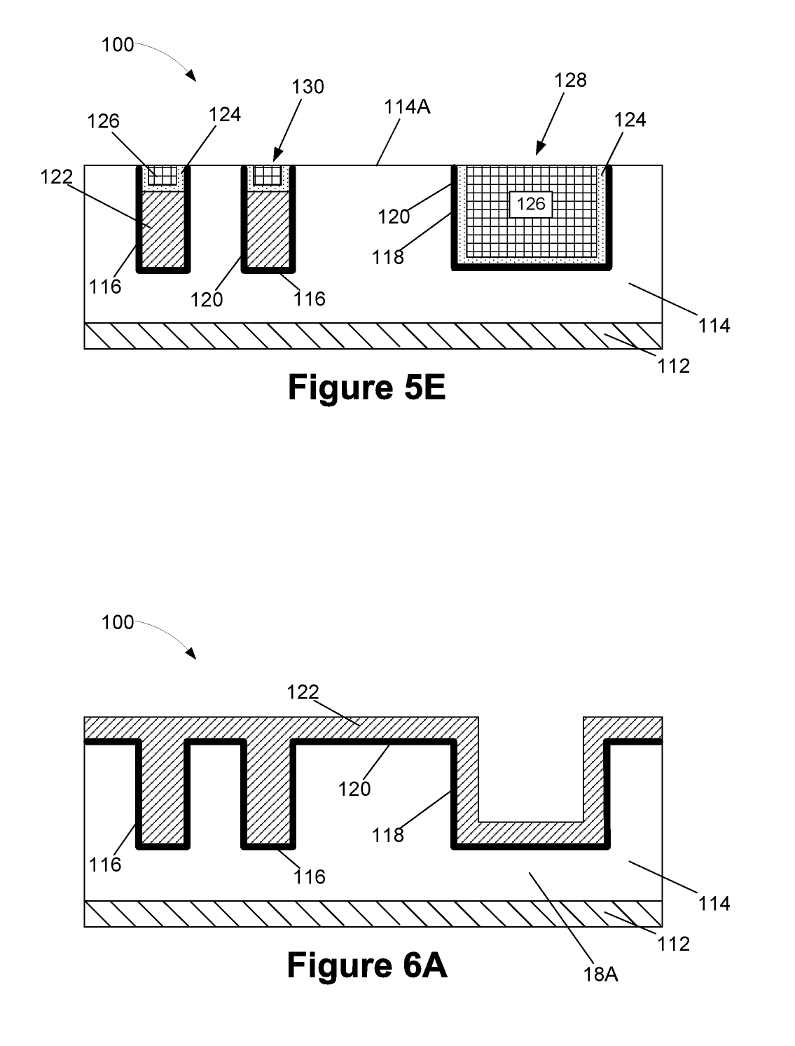

FIGS. 5A-5E depict another illustrative method disclosed herein for forming conductive structures with different material compositions in a metallization layer on the integrated circuit product 100. FIG. 5A depicts the product 100 at a point in fabrication that corresponds to that depicted in FIG. 2A.

FIG. 5B depicts the product 100 after the above-described anneal process 127 was performed on the product 100. As depicted, by performing this anneal process 127, a substantial portion of the sidewalls of the larger trench 118 are effectively cleared of the first bulk metal layer 122, while the portion 122X of the first bulk metal layer 122 remains positioned at the bottom of the wider trench 118.

FIG. 5C depicts the product 100 after the above-described timed, isotropic etching process 123 was performed on the product 100. However, in this embodiment, the etching process 123 was performed for a duration such that, at the completion of etching process 123, the first bulk metal layer 122 is removed from the wider trench 118, while the portions of the first bulk metal layer 122 in the narrower trenches 116 are recessed such that the recessed upper surface 122A of the first bulk metal layer 122 in the trenches 116 is positioned at a level that is about 5-20 nm below the upper surface 114A of the layer of insulating material 114. That is, in this embodiment, after the completion of the etching process 123, the material of the second bulk metal layer 122 does not substantially fill the trenches 116.

FIG. 5D depicts the product 100 after the above-described second barrier layer 124, the seed layer 125 and the second bulk metal layer 126 were formed on the product 100. Note that portions of the layers 124, 125 and 126 extend into the upper portion of the trenches 116 above the recessed material of the second bulk metal layer 122.

FIG. 5E depicts the product 100 after one or more chemical mechanical polishing (CMP) operations were performed to remove the excess amounts of the various materials positioned above the upper surface 114A of the layer of insulating material 114. These operations result in the formation of the wide conductive structure 128 in the wider trench 118 and the narrow conductive structure 130 in each of the relatively narrow trenches 116. As depicted, in this embodiment, the wide conductive structure 128 is comprised of the first barrier layer 120, the second barrier layer 124 and the second bulk metal layer 126, wherein the material of the second bulk metal layer 126 constitutes the bulk conductive portion of the wide conductive structure 128, i.e., the primary metal material of the wide conductive structure 128 other than the barrier layers 120, 124. However, in this embodiment, the narrow conductive structure 130 is comprised of the first barrier layer 120, a portion of the first bulk metal layer 122, the second barrier layer 124 and a portion of the second bulk metal layer 126. However, even in this embodiment, the portion of the first bulk metal layer 122 still constitutes the bulk of the conductive portion of the narrow conductive structure 130, i.e., the primary metal material of the conductive structure 130 other than the barrier layer 120, the barrier layer 124 and the portion of the second bulk metal layer 126. In one illustrative embodiment, the materials of the first bulk metal layer 122 of the narrow conductive structure 130 shown in FIG. 5E may constitute about 60-90 percent of the overall volume of conductive material that, collectively, defines the narrow conductive structure 130.

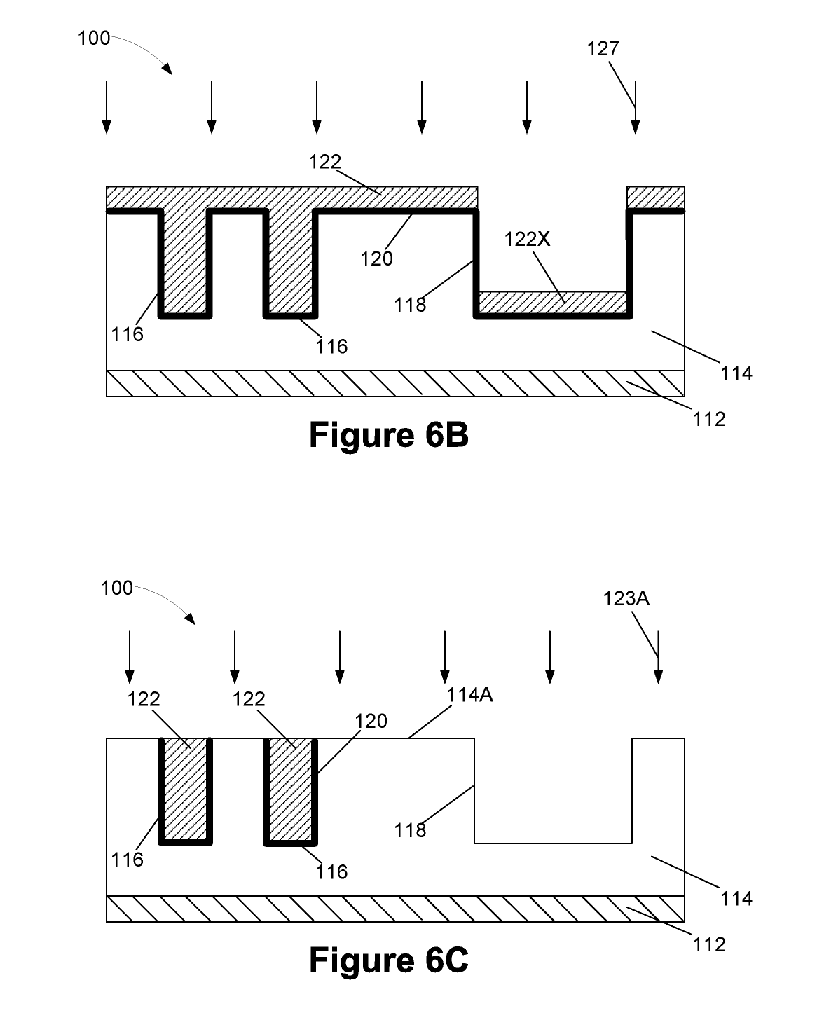

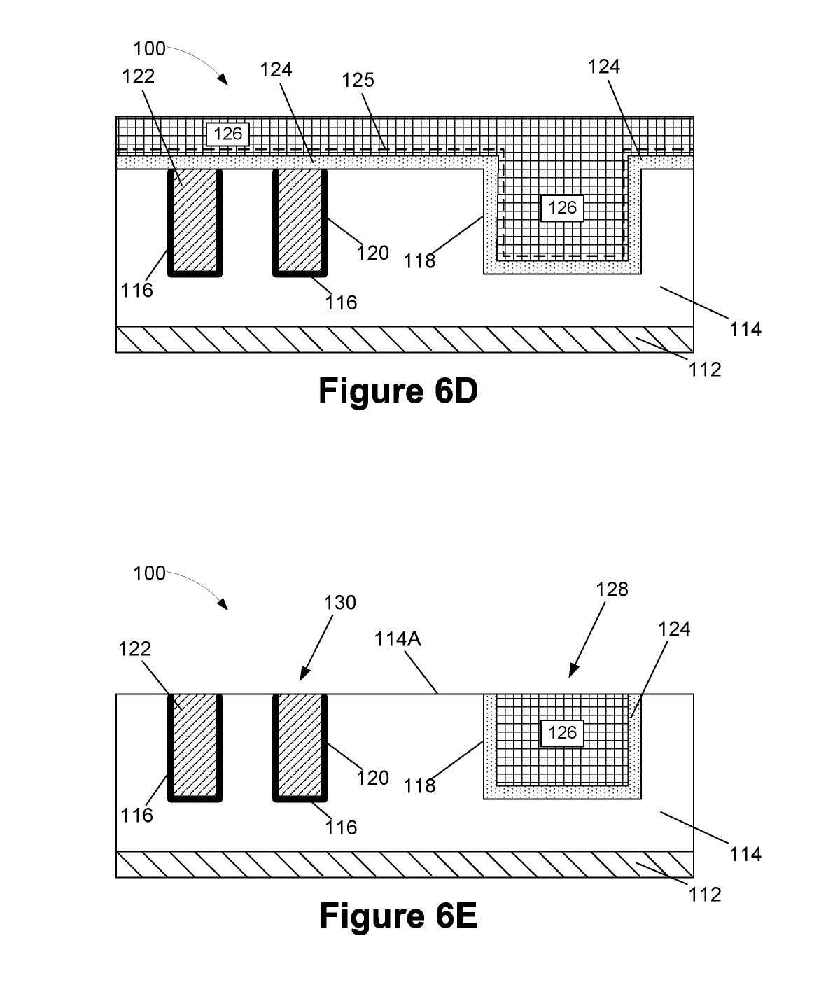

FIGS. 6A-6E depict a further illustrative method disclosed herein for forming conductive structures with different material compositions in a metallization layer on the integrated circuit product 100. FIG. 6A depicts the product 100 at a point in fabrication that corresponds to that depicted in FIG. 2A.

FIG. 6B depicts the product 100 after the above-described anneal process 127 was performed on the product 100. As depicted, by performing this anneal process 127, a substantial portion of the sidewalls of the larger trench 118 are effectively cleared of the first bulk metal layer 122, while a portion 122X of the first bulk metal layer 122 remains positioned at the bottom of the wider trench 118.

FIG. 6C depicts the product after at least one isotropic etching process 123A was performed on the product 100 to remove portions of the first bulk metal layer 122 and portions of the first barrier layer 120. The etch chemistry may need to be changed during the at least one etching process 123A to accomplish the removal of these materials. At the completion of the at least one etching process 123A, substantially all of the first bulk metal layer 122 and the first barrier layer 120 have been removed from the product 100 except within the smaller trenches 116. Note that the material of the first bulk metal layer 122 and the material of the first barrier layer 120 has been cleared from the wider trench 118 and from above the upper surface 114A of the layer of insulating material.

FIG. 6D depicts the product 100 after the above-described second barrier layer 124, the seed layer 125 and the second bulk metal layer 126 were formed on the product 100.

FIG. 6E depicts the product 100 after one or more chemical mechanical polishing (CMP) operations were performed to remove the excess amounts of the various materials positioned above the upper surface 114A of the layer of insulating material 114. These operations result in the formation of the wide conductive structure 128 in the wider trench 118 and the narrow conductive structure 130 in each of the relatively narrow trenches 116. As depicted, in this embodiment, the wide conductive structure 128 is comprised of the second barrier layer 124 and a portion of the second bulk metal layer 126, wherein the portion of the second bulk metal layer 126 constitutes the bulk conductive portion of the wide conductive structure 128, i.e., the primary metal material of the wide conductive structure 128 other than the barrier layer 124. As before, in this embodiment, the narrower conductive structure 130 is comprised of the first barrier layer 120 and the first bulk metal layer 122, wherein the first bulk metal layer 122 constitutes the bulk of the conductive portion of the overall narrow conductive structure 130, i.e., the primary metal material of the narrow conductive structure 130 other than the barrier layer 120.

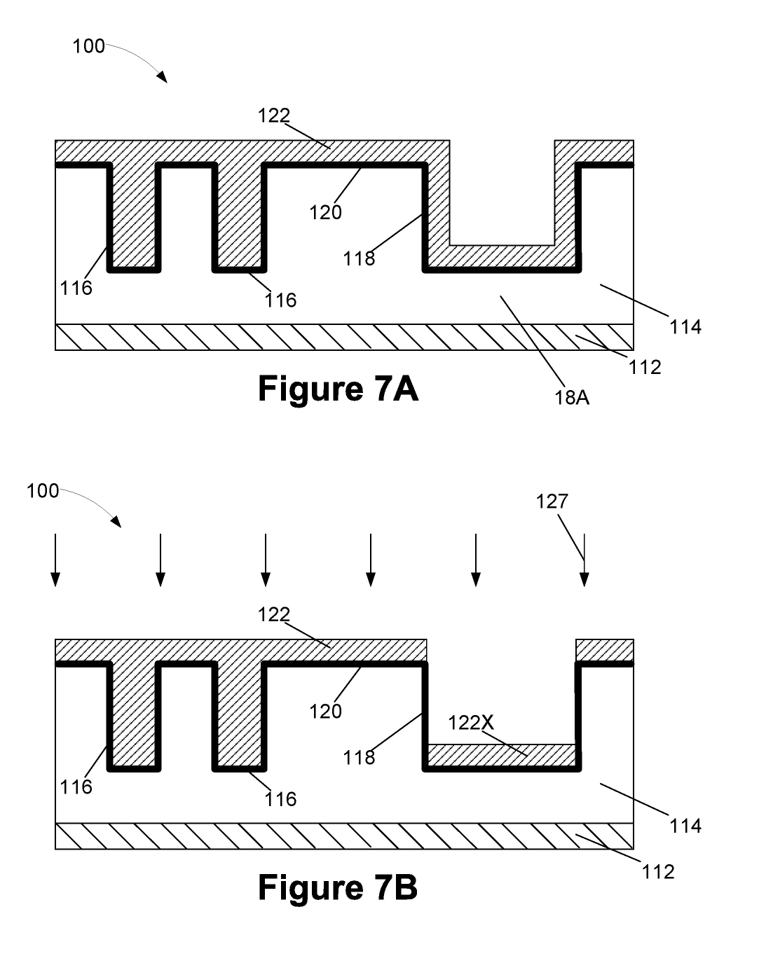

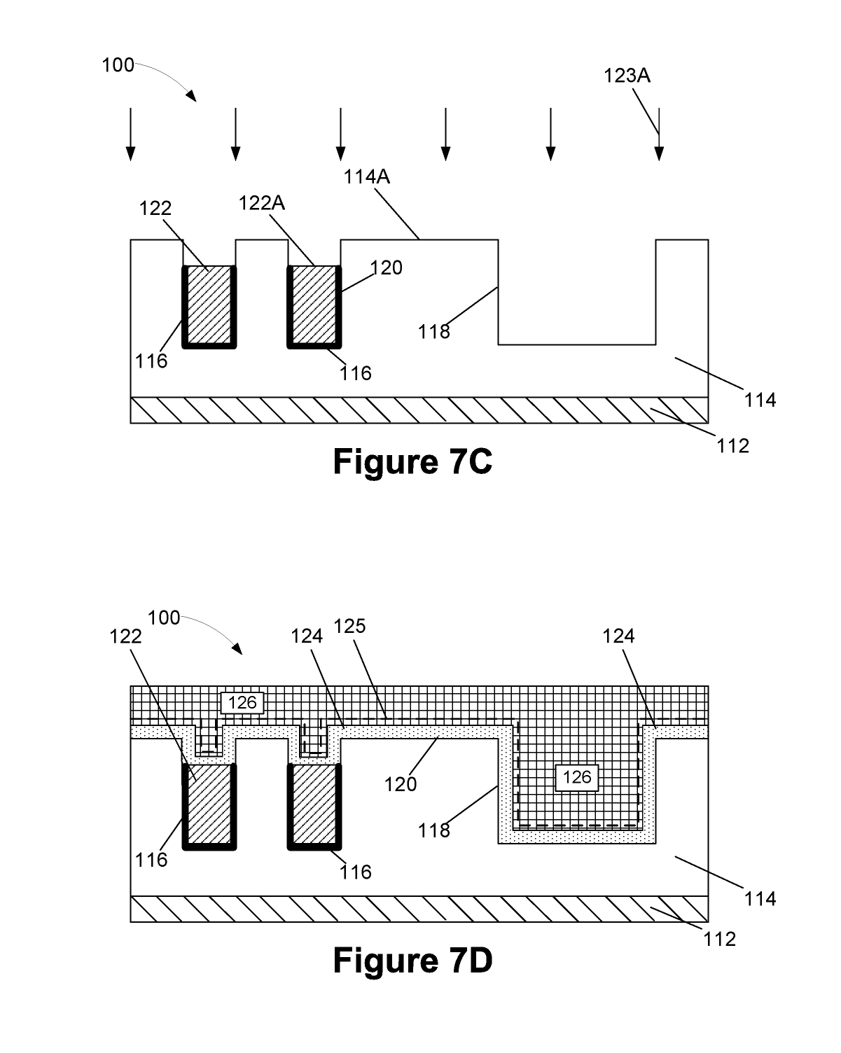

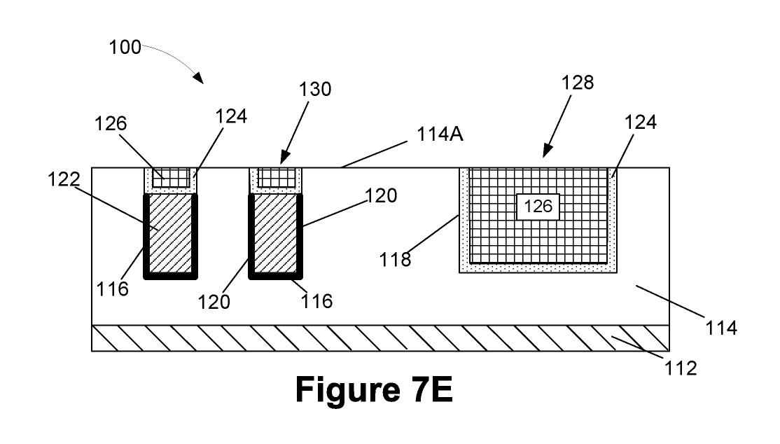

FIGS. 7A-7E depict another illustrative method disclosed herein for forming conductive structures with different material compositions in a metallization layer on the integrated circuit product 100. FIG. 7A depicts the product 100 at a point in fabrication that corresponds to that depicted in FIG. 2A.

FIG. 7B depicts the product 100 after the above-described anneal process 127 was performed on the product 100. As depicted, by performing this anneal process 127, a substantial portion of the sidewalls of the larger trench 118 are effectively cleared of the first bulk metal layer 122, while a portion 122X of the first bulk metal layer 122 remains positioned at the bottom of the wider trench 118.

FIG. 7C depicts the product 100 after the above-described timed, isotropic etching process 123A was performed on the product 100. As noted above, in this embodiment, the etching process 123A was performed for a duration such that, at the completion of the etching process 123A, the barrier layer 120 and the first bulk metal layer 122 are removed from the wider trench 118 while the portions of the first bulk metal layer 122 in the narrower trenches 116 is recessed such that the recessed upper surface 122A of the portions of the first bulk metal layer 122 that remain in the trenches 116 is positioned at a level that is below the upper surface 114A of the layer of insulating material 114.

FIG. 7D depicts the product 100 after the above-described second barrier layer 124, the seed layer 125 and the second bulk metal layer 126 were formed on the product 100. Note that portions of the layers 124, 125 and 126 extend into the upper portion of the trenches 116 above the recessed material of the second bulk metal layer 122.

FIG. 7E depicts the product 100 after one or more chemical mechanical polishing (CMP) operations were performed to remove the excess amounts of the various materials positioned above the upper surface 114A of the layer of insulating material 114. These operations result in the formation of the wide conductive structure 128 in the wider trench 118 and the narrow conductive structure 130 in each of the relatively narrow trenches 116. As depicted, in this embodiment, the wide conductive structure 128 is comprised of the second barrier layer 124 and a portion of the second bulk metal layer 126, wherein the portion of the second bulk metal layer 126 constitutes the bulk conductive portion of the wide conductive structure 128, i.e., the primary metal material of the wide conductive structure 128 other than the second barrier layer 124. However, in this embodiment, the narrow conductive structure 130 is comprised of the first barrier layer 120, a portion of the first bulk metal layer 122, the second barrier layer 124 and a portion of the second bulk metal layer 126. However, even in this embodiment, the portion of the first bulk metal layer 122 still constitutes the bulk of the conductive portion of the narrow conductive structure 130, i.e., the primary metal material of the conductive structure 130 other than the barrier layer 120, the barrier layer 124 and the portion of the second bulk metal layer 126. In one illustrative embodiment, the materials of the first bulk metal layer 122 of the narrow conductive structure 130 shown in FIG. 7E may constitute about 60-90 percent of the overall volume of conductive material that, collectively, define the narrow conductive structure 130.

As will be appreciated by those skilled in the art after a complete reading of the present application, the various methods disclosed herein provide techniques whereby a first bulk metal material, e.g., the first bulk metal layer 122, may be used in forming the relatively narrow conductive structures 130 while the relatively wide conductive structures 128 may be formed using a second bulk metal material, e.g., the second bulk metal layer 126, wherein the materials of the first and second bulk metal layers 122, 126 are different from one another. In one particular embodiment, the bulk portion of the relatively narrow conductive structures 130 may be comprised of a non-copper material, such as cobalt, while the bulk portion of the relatively wide conductive structures 128 may be comprised of copper.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method, comprising:
forming a first trench and a second trench in a layer of insulating material, said first trench having a first lateral critical dimension, said second trench having a second lateral critical dimension that is greater than said first lateral critical dimension of said first trench;
forming a first conductive structure in said first trench, wherein a first bulk metal material constitutes a bulk portion of said first conductive structure; and
forming a second conductive structure in said second trench, wherein a second bulk metal material constitutes a bulk portion of said second conductive structure and wherein said first bulk metal material and said second bulk metal material are different materials.

2. The method of claim 1, wherein said second bulk metal material is copper.

3. The method of claim 2, wherein said first bulk metal material is cobalt.

4. The method of claim 1, wherein said second lateral critical dimension is at least three times greater than said first lateral critical dimension.

5. The method of claim 1, wherein forming said first conductive structure in said first trench comprises:
forming a first barrier layer in said first trench and said second trench;
performing a first conformal deposition process so as to form a first bulk metal layer comprised of said first bulk metal material in said first and second trenches, wherein said first bulk metal layer overfills said first trench but only lines said second trench; and
performing at least one etching process to remove portions of said first bulk metal layer while leaving a remaining portion of said first bulk metal layer positioned in said first trench.

6. The method of claim 5, wherein performing said at least one etching process to remove portions of said first bulk metal layer comprises performing said at least one etching process so as to remove substantially all of said first bulk metal layer from said second trench.

7. The method of claim 5, wherein performing said at least one etching process to remove portions of said first bulk metal layer comprises performing said at least one etching process so as to leave a residual portion of said first bulk metal layer positioned at a bottom of said second trench.

8. The method of claim 5, wherein performing said at least one etching process to remove portions of said first bulk metal layer comprises performing said at least one etching process such that said remaining portion of said first bulk metal layer positioned in said first trench has an upper surface that is substantially planar with an upper surface of said at least one layer of insulating material and said remaining portion of said first bulk metal layer substantially fills said first trench.

9. The method of claim 5, wherein performing said at least one etching process to remove portions of said first bulk metal layer comprises performing said at least one etching process such that said remaining portion of said first bulk metal layer positioned in said first trench has a recessed upper surface that is positioned at a level that is below a level of an upper surface of said at least one layer of insulating material and said remaining portion of said first bulk metal layer does not substantially fill said first trench.

10. A method, comprising:
forming a first trench and a second trench in at least one layer of insulating material, said first trench having a first lateral critical dimension, said second trench having a second lateral critical dimension that is greater than said first lateral critical dimension of said first trench;
depositing a first bulk metal layer in both said first and second trenches;
performing at least one first process operation to remove portions of said first bulk metal layer while leaving a remaining portion of said first bulk metal layer positioned within said first trench;
depositing a second bulk metal layer above said remaining portion of said first bulk metal layer and within said second trench so as to overfill said second trench with said second bulk metal layer, wherein said first bulk metal layer and said second bulk metal layer comprise different materials; and
performing at least one second process operation to remove materials positioned above an upper surface of said at least one layer of insulating material so as to define a narrow conductive structure positioned in said first trench and a wide conductive structure in said second trench.

11. The method of claim 10, wherein, prior to depositing said first bulk metal layer, the method comprises depositing a first barrier layer in both said first and second trenches.

12. The method of claim 11, wherein, prior to depositing said second bulk metal layer, the method comprises depositing a second conductive barrier layer on said first conductive barrier layer within said second trench.

13. The method of claim 12, wherein said narrow conductive structure comprises said first bulk metal layer and said first barrier layer and said wide conductive structure comprises said first barrier layer, said second barrier layer and said second bulk metal layer.

14. The method of claim 11, wherein, prior to depositing said second bulk metal layer, the method comprises removing said first barrier layer from within said second trench.

15. The method of claim 14, wherein, prior to depositing said second bulk metal layer, the method comprises depositing a second conductive barrier layer on and in contact with said at least one layer of insulating material within said second trench.

16. The method of claim 15, wherein said narrow conductive structure comprises said first bulk metal layer and said first barrier layer and said wide conductive structure comprises said second barrier layer and said second bulk metal layer and said first barrier layer is not present in said wide conductive structure.

17. The method of claim 12, wherein said first and second barrier layers are comprised of different materials.

18. A method, comprising:
forming a first trench and a second trench in at least one layer of insulating material, said first trench having a first lateral critical dimension, said second trench having a second lateral critical dimension that is greater than said first lateral critical dimension of said first trench;
depositing a first barrier layer in both said first and second trenches;
depositing a first bulk metal layer on said first barrier layer in both said first and second trenches, wherein said first bulk metal layer overfills said first trench but only lines said second trench;
performing at least one first process operation to remove portions of said first bulk metal layer while leaving a remaining portion of said first bulk metal layer positioned within said first trench;
depositing a second barrier layer above said at least one layer of insulating material and on and in contact with said first barrier layer within said second trench;
depositing a second bulk metal layer above said remaining portion of said first bulk metal layer and within said second trench above said second barrier layer so as to overfill said second trench with said second bulk metal layer, wherein said first bulk metal layer and said second bulk metal layer comprise different materials; and
performing at least one second process operation to remove materials positioned above an upper surface of said at least one layer of insulating material so as to define a narrow conductive structure positioned in said first trench and a wide conductive structure in said second trench, said narrow conductive structure comprising said first bulk metal layer and said first barrier layer and said wide conductive structure comprising said first barrier layer, said second barrier layer and said second bulk metal layer.

19. The method of claim 18, wherein said first and second barrier layers are comprised of different materials.

20. The method of claim 18, wherein said second bulk metal layer is a metal layer comprising copper and said first bulk metal layer is a metal layer comprising cobalt.

21. The method of claim 18, wherein said second lateral critical dimension is at least three times greater than said first lateral critical dimension.

22. A method, comprising:
forming a first trench and a second trench in at least one layer of insulating material, said first trench having a first lateral critical dimension, said second trench having a second lateral critical dimension that is greater than said first lateral critical dimension of said first trench;
depositing a first barrier layer in both said first and second trenches;
depositing a first bulk metal layer on said first barrier layer in both said first and second trenches, wherein said first bulk metal layer overfills said first trench but only lines said second trench;
performing at least one first process operation to remove portions of said first barrier layer and said first bulk metal layer from within said second trench while leaving a remaining portion of said first barrier layer and said first bulk metal layer positioned within said first trench;
depositing a second barrier layer above said at least one layer of insulating material on and in contact with said first barrier layer within said second trench and within said second trench, wherein said second barrier layer is deposited on and in contact with said layer of insulating material within said second trench depositing a second bulk metal layer above said remaining portion of said first bulk metal layer and within said second trench above said second barrier layer so as to overfill said second trench with said second bulk metal layer, wherein said first bulk metal layer and said second bulk metal layer comprise different materials; and
performing at least one second process operation to remove materials positioned above an upper surface of said at least one layer of insulating material so as to define a narrow conductive structure positioned in said first trench and a wide conductive structure in said second trench, said narrow conductive structure comprising said first bulk metal layer and said first barrier layer and said wide conductive structure comprising said second barrier layer and said second bulk metal layer.

23. The method of claim 22, wherein said second bulk metal layer is a metal layer comprising copper and said first bulk metal layer is a metal layer comprising cobalt.

24. The method of claim 22, wherein said second lateral critical dimension is at least three times greater than said first lateral critical dimension.
